(19) United States
(12) Patent Application Publication
(10) Pub. No.: US 2026/0022448 A1
(43) Pub. Date: Jan. 22, 2026

(54) DEPOSITION APPARATUS

(71) Applicant: Samsung Display Co., LTD., Yongin-si (KR)

(72) Inventors: JUNGHYUN AHN, Yongin-si (KR); JAESUK MOON, Yongin-si (KR); SEUNGJIN LEE, Yongin-si (KR)

(21) Appl. No.: 19/265,659

(22) Filed: Jul. 10, 2025

(30) Foreign Application Priority Data
Jul. 19, 2024 (KR) 10-2024-0095750

(51) Int. Cl. C23C 14/04; H10K 59/12; H10K 71/16

(52) U.S. Cl. CPC C23C 14/042; H10K 59/1201; H10K 71/166

(57) ABSTRACT

Provided is a deposition apparatus including a deposition chamber which provides an inner space, a deposition source provided in the inner space, a plate provided in the inner space and rotatable, a plurality of magnetic patterns arranged on a surface of the plate, and a plurality of masks disposed between the plate and the deposition source. The plate includes a center plate which is rotatable, a first plate which is coupled to one side of the center plate, and a second plate which is coupled to the other side of the center plate opposing the one side. The plate undergoes a change in mode to a first mode or a second mode through rotation, and the first plate in the first mode and the first plate in the second mode include the plurality of magnetic patterns having different arrays from each other.

This application claims priority to Korean Patent Application No. 10-2024-0095750, filed on Jul. 19, 2024, and all the benefits accruing therefrom under 35 U.S.C. § 119, the content of which in its entirety is incorporated by reference.

### BACKGROUND

The present disclosure herein relates to a deposition apparatus, and more particularly, to a deposition apparatus using a metal mask.

Recently, with the technical development of displays, display techniques are applied to large-sized electronic products in addition to small-sized electronic products. Various devices such as an organic light emitting display device, a liquid crystal display device, and a plasma display device, are mainly used in those displays.

To manufacture the displays, a deposition process of vaporizing a material such as metal to form a thin film is used. The deposition process may be mainly used to form a thin film transistor, form a circuit, or form a component such as a light emitting layer of the display. To perform the process of depositing the thin film, a mask opened to correspond to an area on which the thin film is formed is disposed on a substrate, and then a material to be deposited on the substrate is vaporized under a vacuum atmosphere.

Here, when the mask moves or is not firmly fixed, the material may be deposited even on an area in which a deposition area is not supposed to be formed. In this case, a circuit may be formed even on an area in which the circuit is not supposed to be formed, or product defects such as misalignment due to an error in deposition area may occur in a process to be subsequently performed.

### SUMMARY

The present disclosure provides a deposition apparatus capable of uniformly applying a magnetic force to a mask so as to stabilize bonding between a substrate and the mask.

An embodiment as described herein provides a deposition apparatus including a deposition chamber which provides an inner space, a deposition source provided in the inner space, a plate provided in the inner space and rotatable, a plurality of magnetic patterns arranged on a surface of the plate and in n rows and m columns, where n and m are each a natural number of 1 or more, and a plurality of masks disposed between the plate and the deposition source and fixed by the plurality of magnetic patterns. The plate includes a center plate on which magnetic patterns of a center group are disposed and which is rotatable, a first plate on which magnetic patterns of a first group are disposed and which is coupled to one side of the center plate, and a second plate on which magnetic patterns of a second group are disposed and which is coupled to the other side of the center plate opposing the one side. The plate undergoes a change in mode from a first mode or a second mode through rotation, and the first plate in the first mode and the first plate in the second mode include the plurality of magnetic patterns having different arrays from each other.

In an embodiment, the center plate may rotate about 90 degrees clockwise or counter-clockwise to undergo the change in mode to the first mode or the second mode.

In an embodiment, in the first mode, the plurality of masks may be arranged along the first direction, and each of the plurality of magnetic patterns may face a first magnetic pattern having the same polarity in the first direction, and face a second magnetic pattern having a different polarity in a second direction parallel to a column direction of the plurality of magnetic patterns.

In an embodiment, at least one of the plurality of masks may overlap only one of the center plate, the first plate, and the second plate.

In an embodiment, in the second mode, the plurality of masks may be arranged along the second direction crossing the first direction, and each of the plurality of magnetic patterns may face a third magnetic pattern having the same polarity in the second direction, and face the second magnetic pattern having a different polarity in the second direction parallel to the column direction of the plurality of magnetic patterns.

In an embodiment, at least one of the plurality of masks may overlap all of the center plate, the first plate, and the second plate.

In an embodiment, m may be less than n.

In an embodiment, the center plate may have an N-polygonal shape, and the center plate may rotate about 360/N degrees clockwise or counter-clockwise in the first mode to undergo the change in mode to the second mode.

In an embodiment, the center plate may have a square shape, and each of the first plate and the second plate may have a rectangular shape.

In an embodiment, each of the masks may be a fine metal mask (FMM).

In an embodiment, the deposition apparatus according to an embodiment as described herein may further include a coupling part which couples the center plate and the first plate or the center plate and the second plate to each other, and the first plate or the second plate may be detachable from the coupling part.

In an embodiment as described herein, a deposition apparatus includes a deposition chamber which provides an inner space, a deposition source provided in the inner space, a plurality of masks disposed apart from the deposition source and arranged along one direction, and a mask fixing part which is rotatable clockwise or counter-clockwise on a plane and fixes the masks. The mask fixing part may include a plate provided in the inner space and rotatable, a plurality of first magnetic patterns each having a first polarity, and a plurality of second magnetic patterns each having a second polarity different from the first polarity and spaced apart from the plurality of first magnetic patterns, the plurality of first magnetic patterns and the plurality of second magnetic patterns being disposed on the plate. The first plurality of magnetic patterns may be arranged along an intersection direction crossing the one direction, the second plurality of magnetic patterns may be arranged along the intersection direction, and the first plurality of magnetic patterns and the second plurality of magnetic patterns may be alternately arranged along the one direction.

In an embodiment, the deposition chamber may include a bottom surface defined by a first direction and a second direction crossing each other, and the mask fixing part may undergo a change in mode to a first mode or a second mode through rotation. In the first mode, the one direction may be parallel to the first direction, and, in the second mode, the one direction may be parallel to the second direction.

In an embodiment, the plate may include a center plate which is rotatable, and a first plate and a second plate, where, in the first mode, the first plate and the second plate are disposed apart from each other with the center plate therebetween in the first direction, and, in the second mode, the first plate and the second plate are disposed apart from each other with the center plate therebetween in the second direction. The center plate may rotate clockwise or counter-clockwise to undergo the change in mode to the first mode or the second mode.

In an embodiment, in the first mode, the first plate may include a first group in which first magnetic patterns having different polarities are arranged along the second direction, and, in the second mode, the first plate may include a second group in the second mode in which second magnetic patterns having the different polarities are arranged along the first direction.

In an embodiment, the first plate and the second plate may be detachable from the center plate.

In an embodiment, a difference in angle of rotation between the first mode and the second mode may be about 90 degrees.

In an embodiment, magnetic patterns disposed on the center plate may be arranged in a rows and a columns, and a may be a natural number of 1 or more.

In an embodiment, magnetic patterns may be arranged in a form of a matrix with n rows and m columns. The n rows may be defined in the one direction, the m columns may be defined in the intersection direction, and n and m may be each a natural number of 1 or more.

In an embodiment, n may be less than m.

### BRIEF DESCRIPTION OF THE FIGURES

The accompanying drawings are included to provide a further understanding of the embodiments described herein, and are incorporated in and constitute a part of this specification. The drawings illustrate embodiments and, together with the description, serve to explain principles of the various embodiments.

In the drawings:

FIG. 1 is a view illustrating a deposition apparatus according to an embodiment as described herein;

FIG. 2A is a perspective view of a mask according to an embodiment as described herein;

FIG. 2B is a perspective view illustrating an arrangement of a plurality of masks and a substrate;

FIG. 2C is a plan view illustrating a partial area illustrated in FIG. 2B;

FIGS. 3A and 3B are cross-sectional views illustrating some steps of a method for manufacturing a display device according to an embodiment as described herein;

FIG. 3C is a cross-sectional view illustrating a display panel according to an embodiment as described herein;

FIG. 4A is a perspective view illustrating a mask fixing part according to an embodiment as described herein;

FIG. 4B is a disassembled perspective view of the mask fixing part illustrated in FIG. 4A;

FIG. 4C is a rear view of the mask fixing part illustrated in FIG. 4A;

FIG. 5A is a perspective view illustrating a mask fixing part according to an embodiment as described herein;

FIG. 5B is a disassembled perspective view of the mask fixing part illustrated in FIG. 5A;

FIG. 5C is a rear view of the mask fixing part illustrated in FIG. 5A;

FIG. 6A illustrates magnetic patterns according to a comparative example of an embodiment as described herein;

FIG. 6B is a graph illustrating a magnetic force distribution for positions of the magnetic patterns illustrated in FIG. 6A;

FIG. 7A illustrates magnetic patterns according to a comparative example of an embodiment as described herein; and

FIGS. 7B and 7C are each a graph illustrating a magnetic force distribution for positions of the magnetic patterns illustrated in FIG. 7A.

### DETAILED DESCRIPTION

One or more embodiments are now described more fully hereinafter with reference to the accompanying drawings, in which various embodiments are shown. One or more embodiments may, however, be implemented in many different forms, and should not be construed as limited to the embodiments set forth herein. Rather, these embodiments are provided so that this disclosure will be thorough and complete, and will fully convey the scope of the claims to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In the present disclosure, it will be understood that when an element (or region, layer, section, etc.) is referred to as being “on”, “connected to” or “coupled to” another element, it can be disposed directly on, connected or coupled to the other element or a third element may be disposed between the elements.

Like reference numbers or symbols refer to like elements throughout. In addition, in the drawings, the thickness, the ratio, and the dimension of elements are exaggerated for effective description of the technical contents.

The term “and/or” includes one or more combinations which may be defined by relevant elements.

It will be understood that, although the terms first, second, etc. may be used herein to describe various elements, these elements should not be limited by these terms. These terms are only used to distinguish one element from another element. For example, a first element could be termed a second element without departing from the teachings of the present disclosure, and similarly, a second element could be termed a first element. As used herein, the singular forms are intended to include the plural forms as well, unless the context clearly indicates otherwise.

In addition, the terms, such as “below”, “beneath”, “on” and “above”, are used for explaining the relation of elements shown in the drawings. The terms are relative concept and are explained based on the direction shown in the drawing.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms such as “includes” or “has”, when used herein, specify the presence of stated features, numerals, steps, operations, elements, parts, or the combination thereof, but do not preclude the presence or addition of one or more other features, numerals, steps, operations, elements, parts, or the combination thereof.

Hereinafter, embodiments are described with reference to the accompanying drawings.

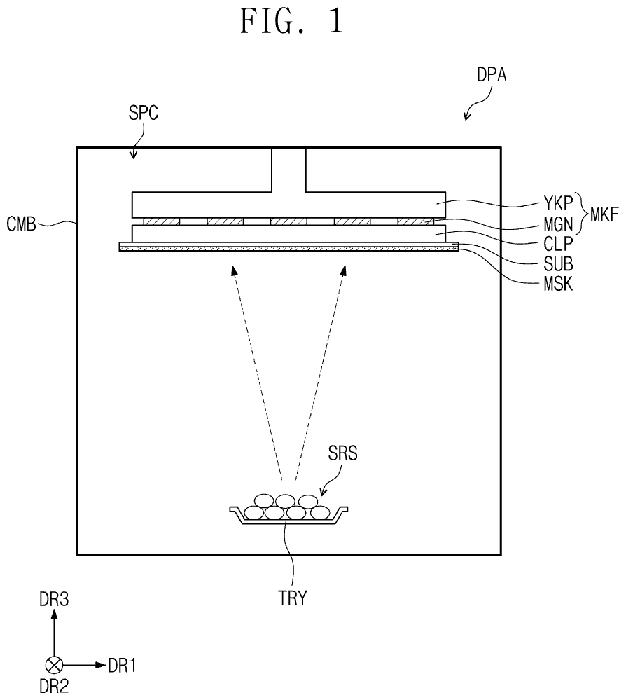

FIG. 1 is a view illustrating a deposition apparatus according to an embodiment as described herein. A deposition apparatus DPA includes a deposition chamber CMB, a deposition material supply part TRY, a mask fixing part MKF, and a substrate fixing part CLP.

The deposition chamber CMB provides a predetermined inner space SPC. The inner space SPC may have a pillar shape having a bottom surface parallel to a plane defined by a first direction DR1 and a second direction DR2, and a height defined by a third direction DR3. The deposition material supply part TRY, the mask fixing part MKF, and the substrate fixing part CLP are provided in the inner space SPC.

The inner space SPC may be in a vacuum state during a deposition process. The vacuum state may be a near-vacuum state or a state in which inert gas is injected into the deposition chamber CMB to reduce a difference in pressure between the inside and the outside of the deposition chamber CMB, and is not limited to any one embodiment.

A deposition source SRS is provided to the deposition material supply part TRY. The deposition source SRS is vaporized to be provided in the inner space SPC during the deposition process. The deposition source SRS may include various materials such as a metal, a metal oxide, or an organic substance to form a thin film. In this embodiment, an organic substance is described as an example of the deposition source SRS, but other embodiments are not so limited.

The substrate fixing part CLP includes a surface on which a substrate SUB is disposed. A mask MSK may be at least partially disposed on the substrate SUB. That is, a first surface of the substrate SUB may face the substrate fixing part CLP, and a second surface opposing the first surface may face the mask MSK and the deposition source SRS. The deposition source SRS may be vaporized and deposited on the other surface of the substrate SUB through the mask MSK.

The mask fixing part MKF may include a plurality of magnetic patterns MGN and a plate YKP. The magnetic patterns MGN may be disposed between the plate YKP and the substrate fixing part CLP. The magnetic patterns MGN may have a magnetic force strong enough to pass through the substrate fixing part CLP and the substrate SUB to reach the mask MSK. The mask fixing part MKF may fix the mask MSK, and the mask MSK may be in close contact with the substrate SUB.

The plate YKP may be coupled to a ceiling of the deposition chamber CMB, but this is illustrated as an example. The plate YKP may be supported by being coupled to a separate structure, and is not limited to any one embodiment. The plate YKP may rotate on a plane defined by the first direction DR1 and the second direction DR2. Specifically, a rotary shaft of the plate YKP may be substantially perpendicular to a bottom surface of the deposition chamber CMB. The plurality of magnetic patterns MGN may be rotated on a plane through the rotation of the plate YKP. The rotation of the magnetic patterns MGN may be substantially controlled by the plate YKP. This will be described later in detail.

According to an embodiment, as the mask fixing part MKF capable of rotating is provided, the mask fixing part MKF may stably fix the masks MSK even when an arrangement position or design of the masks MSK is changed according to a size or a disposed position of the substrate.

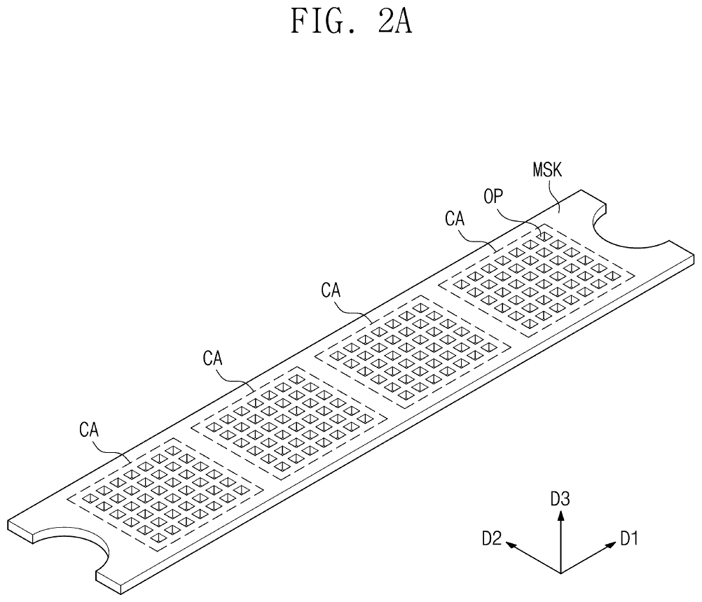

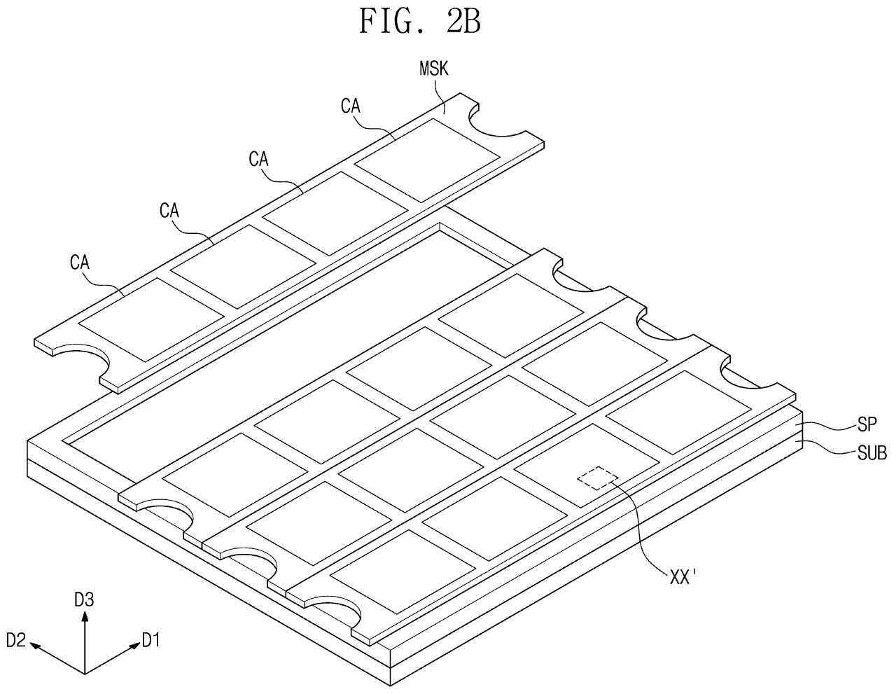

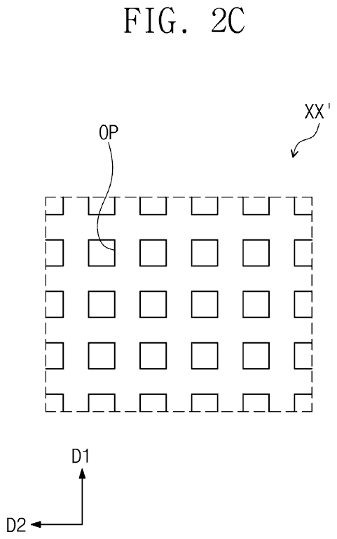

FIG. 2A is a perspective view of a mask according to an embodiment as described herein. FIG. 2B is a perspective view illustrating an arrangement of a plurality of masks and a substrate. FIG. 2C is a plan view illustrating a partial area illustrated in FIG. 2B. Hereinafter, an embodiment is described with reference to FIGS. 2A to 2C.

As illustrated in FIG. 2A, each of masks MSK may be a metal mask, specifically a fine metal mask (FMM). One mask MSK may include a plurality of cell areas CA arranged along the first direction D1. In this embodiment, the cell areas CA is provided in four, and the four cell areas CA are disposed apart from each other. However, this is illustrated as an example, and other numbers of cell areas CA can be implemented in other embodiments. The mask MSK may include more cell areas CA, and the cell areas CA may be arranged along the second direction D2 crossing the first direction D1, and are not limited to any one embodiment.

A plurality of through-portions OP may be defined in each of the cell areas CA. The through-portions OP may be arranged apart from each other along the first direction D1 and the second direction D2. Each of the through-portions OP may be defined to pass through the mask MSK in a thickness direction D3 (hereinafter referred to as a third direction) of the metal mask MSK.

As illustrated in FIGS. 2B and 2C, the mask MSK is disposed on a substrate SUB. In this embodiment, the plurality of masks MSK arranged along the first direction D1 are provided. However, the mask MSK is not limited thereto, and may be provided as one.

In this embodiment, a support SP may be further disposed between the masks MSK and the substrate SUB. The support SP may be provided in the form of a frame that exposes at least a portion of the substrate SUB. The masks MSK may be coupled to the support SP and provided as one body.

The portion of the substrate SUB exposed by the support SP may overlap cell areas CA in which respective through-portions OP of the masks MSK are defined. Referring to FIG. 2C, an enlarged area of area XX′ in which the through-portions OP are arranged apart from each other along the first direction D1 and the second direction D2 is illustrated.

In this embodiment, the support SP prevents direct contact between the masks MSK and the substrate SUB. Accordingly, the substrate SUB may be prevented from being damaged due to contact with the masks MSK. However, this is illustrated as an example. In a method for manufacturing a display panel according to an embodiment, the support SP may be omitted, and the masks MSK may be directly disposed on the substrate SUB, and are not limited to any one embodiment.

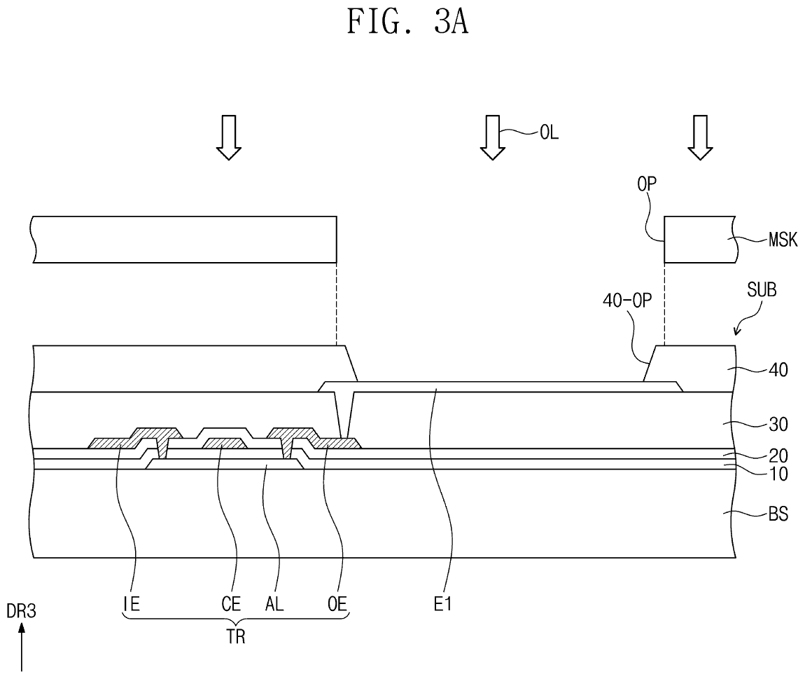

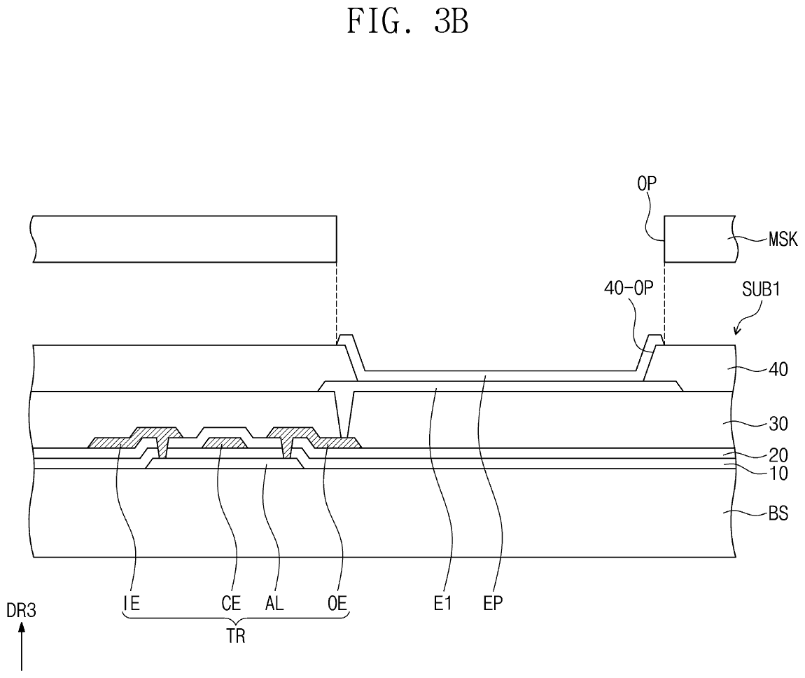

FIGS. 3A and 3B are cross-sectional views illustrating some steps of a method for manufacturing a display device according to an embodiment as described herein. FIG. 3A illustrates a step in which a mask MSK is provided on a substrate SUB, and FIG. 3B illustrates a step in which the deposition source SRS (see FIG. 1) is deposited on the substrate SUB. That is, FIG. 3A may correspond to one illustrating a state in which the mask MSK is provided in the deposition apparatus DPA (see FIG. 1), and FIG. 3B may correspond to one illustrating a state in which a deposition pattern is formed in the deposition apparatus DPA. Hereinafter, an embodiment is described with reference to FIGS. 3A and 3B.

Referring to FIG. 3A, the substrate SUB may be in a state in which a transistor TR, a plurality of insulating layers 10, 20, 30 and 40, and a lower electrode E1 are formed on a base layer BS. The base layer BS may include a plastic substrate, a glass substrate, a metal substrate, or the like. The plastic substrate includes a resin. For example, the base layer BS may include at least one of an acrylate resin, a methacrylate resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

The transistor TR is disposed on the base layer BS. The transistor TR is provided in plurality, and the plurality of transistors TR are disposed in through-portions OP, respectively. In this embodiment, for concise explanation, one transistor TR disposed in one through-portion OP is illustrated. However, this is illustrated as an example, and the transistor TR overlapping the one through-portion OP may be provided in plurality, and is not limited to any one embodiment.

The transistor TR includes a semiconductor pattern AL, a control electrode CE, an input electrode IE, and an output electrode OE. The semiconductor pattern AL may include a semiconductor material. For example, the semiconductor pattern AL may include silicon or a metal oxide.

The control electrode CE is disposed on a first insulating layer 10. The control electrode CE may overlap the semiconductor pattern AL on a plane, and be disposed apart from the semiconductor pattern AL on a cross-section. The control electrode CE is spaced apart from the semiconductor pattern AL with the first insulating layer 10 therebetween. However, this is illustrated as an example, and, in the transistor TR according to an embodiment, the semiconductor pattern AL may be disposed on the control electrode CE and is not limited to any one embodiment.

The input electrode IE and the output electrode OE are disposed on a second insulating layer 20. The input electrode IE and the output electrode OE may be disposed apart from each other on a plane. Each of the input electrode IE and the output electrode OE may pass through the first insulating layer 10 and the second insulating layer 20 and be connected to the semiconductor pattern AL.

However, this is illustrated as an example, and, in the transistor TR according to an embodiment, the input electrode IE and the output electrode OE may be disposed below the semiconductor pattern AL, or disposed between the control electrode CE and the semiconductor pattern AL. Alternatively, the input electrode IE and the output electrode OE may be disposed on the same layer as the semiconductor pattern AL to be in direct contact with the semiconductor pattern AL. The transistor TR according to an embodiment may be designed in various structures, and is not limited to any one embodiment.

The lower electrode E1 is disposed on a third insulating layer 30. The third insulating layer 30 is disposed on the transistor TR to cover the transistor TR. The third insulating layer 30 may include an organic substance and/or an inorganic substance.

The lower electrode E1 may pass through the third insulating layer 30 and be connected to the transistor TR that is a thin-film transistor. Although not illustrated, an initial substrate DP-I1 may further include a separate connection electrode disposed between the lower electrode E1 and the thin-film transistor TR, and here, the lower electrode E1 may be electrically connected to the thin-film transistor TR through the connection electrode.

A fourth insulating layer 40 is disposed on the third insulating layer 30. A predetermined opening portion 40-OP (hereinafter referred to as an opening portion) may be defined in the fourth insulating layer 40. The opening portion 40-OP is defined in a position corresponding to the lower electrode E1, and exposes at least a portion of the lower electrode E1.

In this embodiment, the through-portion OP of the mask MSK that is a metal mask may be provided in a position corresponding to the opening portion 40-OP of the fourth insulating layer 40. The metal mask MSK may selectively pattern only the opening portion 40-OP of the fourth insulating layer 40 through the through-portion OP. This will be described in more detail with reference to FIG. 3B.

Referring to FIGS. 3A and 3B, an emission pattern EP may be formed on the substrate SUB to form an initial substrate SUB1. The emission pattern EP may be formed by patterning a patterning material OL on an initial substrate EP-I1. For example, the patterning material OL may be deposited on a position of the through-portion OP by using the metal mask MSK to form the emission pattern EP. However, this is illustrated as an example, and, as long as the metal mask MSK is available, the emission pattern EP according to an embodiment may also be formed through a solution process such as printing, and is not limited to any one embodiment.

The patterning material OL may include a light emitting material. For example, the patterning material OL may include at least one of materials emitting red, green, and blue light, and may include a fluorescent material or a phosphorescent material. The light emitting material may be activated in response to an electrical signal and display light. The patterning material OL may include an organic light emitting material or an inorganic light emitting material.

The emission pattern EP is provided in plurality, and the plurality of emission patterns EP are disposed in opening portions, respectively. In this embodiment, for concise explanation, one emission pattern EP disposed in one opening portion 40-OP is illustrated.

However, this is illustrated as an example, and the emission pattern EP disposed in the one opening portion 40-OP may be provided in plurality. Alternatively, the one emission pattern EP may overlap a plurality of opening portions. The emission pattern EP according to an embodiment may have various shapes, and is not limited to any one embodiment.

Referring to FIG. 3B, the emission patterns EP are formed in the opening portion 40-OP. The lower electrode E1 having been exposed by the opening portion 40-OP may be covered by the emission pattern EP.

Then, FIG. 3C illustrates a cross-sectional view of a display panel DP. As illustrated in FIG. 3C, an upper electrode E2 and an encapsulation layer 50 are formed in sequence on the emission pattern EP, thereby forming the display panel DP. The upper electrode E2 is disposed on the emission pattern EP. The upper electrode E2 is illustrated as having a shape of one body overlapping a plurality of emission patterns. However, this is illustrated as an example. The upper electrode E2 may be provided in plurality, and the plurality of upper electrodes E2 may be disposed on the emission patterns, respectively.

The encapsulation layer 50 covers a light emitting element ED. The encapsulation layer 50 may include a first inorganic film 51, an organic film 52, and a second inorganic film 53. The first inorganic film 51 and the second inorganic film 53 may each include a silicon nitride, a silicon oxide, or a compound as a combination thereof. The first inorganic film 51 and the second inorganic film 53 may each be formed through a deposition process such as chemical vapor deposition (CVD).

The organic layer 52 may provide a flat surface on the first inorganic film 51. Unevenness formed on a top surface of the first inorganic film 51, particles present on the first inorganic film 51, or the like may be covered by the organic film 52, thereby preventing a surface state of the top surface of the first inorganic film 51 from affecting components such as the second inorganic film 53 formed on the organic film 52. In addition, the organic film 52 may alleviate stress between layers that are in contact with each other. The organic film 52 may include an organic substance, and may be formed through a solution process such as spin coating, slit coating, or inkjet process.

A pattern may be selectively formed only on an area corresponding to the through-portion OP by using the deposition apparatus DPA according to an embodiment. Accordingly, the display panel DP including the light emitting element ED may be easily formed.

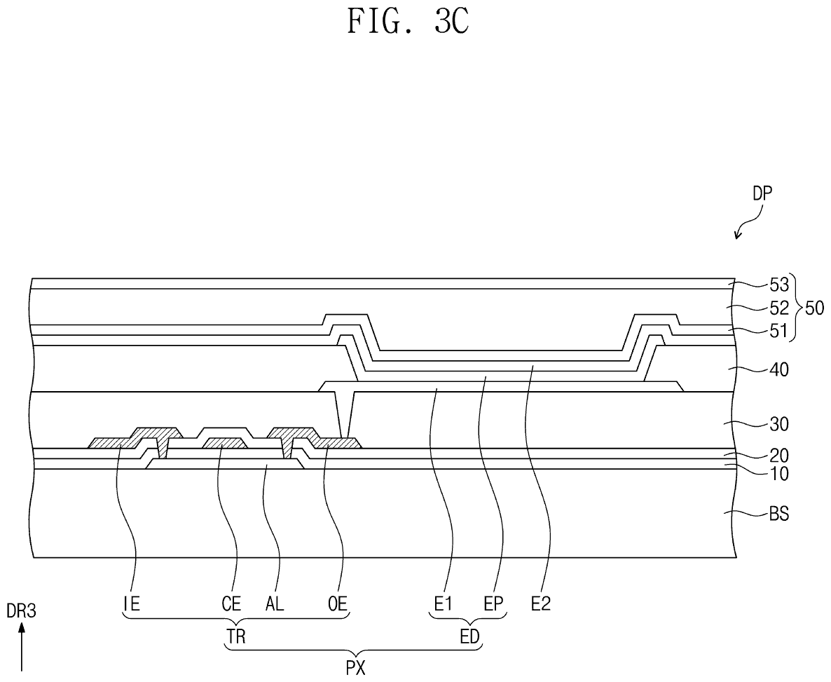

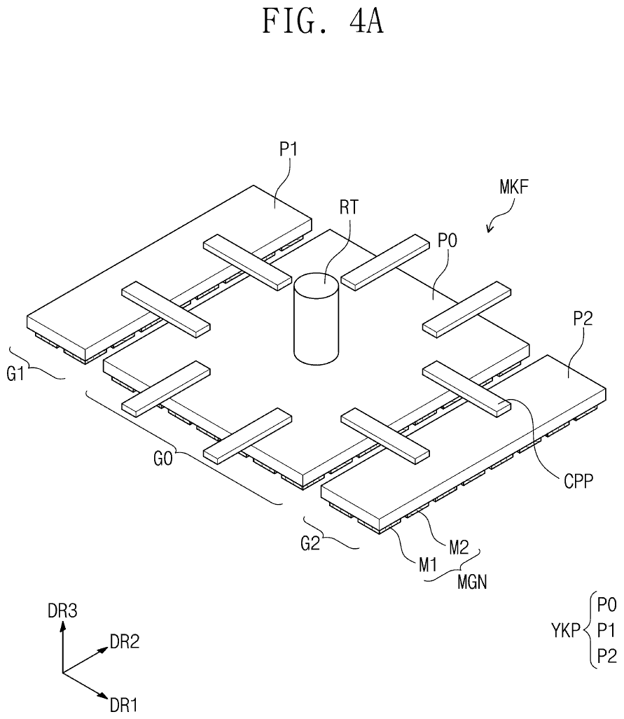

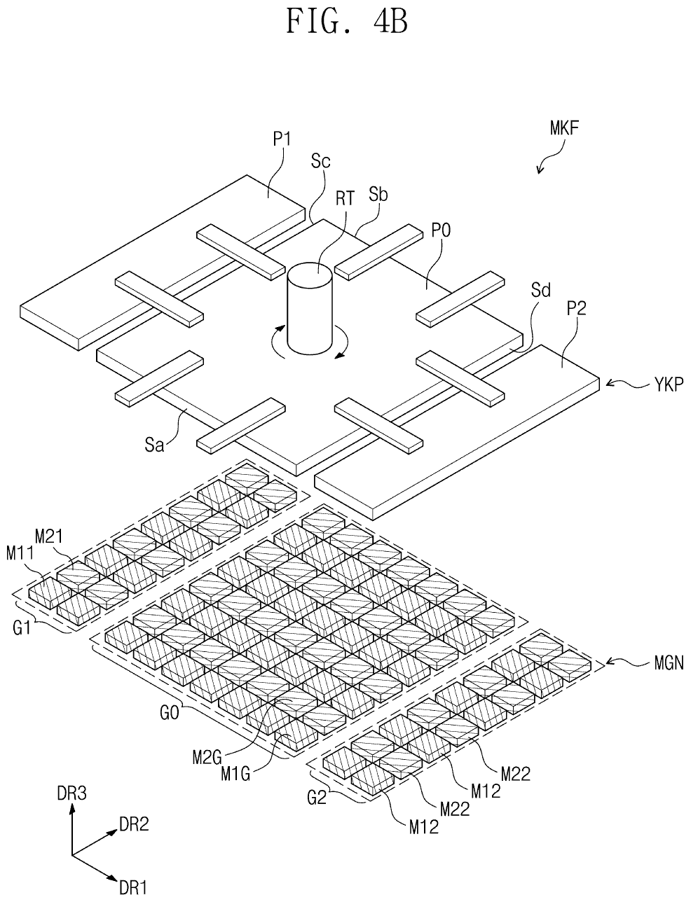

FIG. 4A is a perspective view illustrating a mask fixing part according to an embodiment as described herein. FIG. 4B is a disassembled perspective view of the mask fixing part illustrated in FIG. 4A. FIG. 4C is a rear view of the mask fixing part illustrated in FIG. 4A. Hereinafter, an embodiment is described with reference to FIGS. 4A to 4C.

As illustrated in FIGS. 4A and 4B, a mask fixing part MKF may include a rotary shaft RT, a plurality of plates P0, P1 and P2, a plurality of coupling parts CPP, and a plurality of magnetic patterns MGN (e.g., M1, M2, . . . etc.). The rotary shaft RT may have a pillar shape extending in the third direction DR3. In this embodiment, the rotary shaft RT is illustrated as having a cylindrical shape, but is not limited thereto. The rotary shaft RT may perform a rotational motion on a plane defined by the first direction DR1 and the second direction DR2, and through the rotation of the rotary shaft RT, the mask fixing part MKF may undergo a change in mode to a first mode or a change in mode to a second mode. The first mode and the second mode may be divided according to an arrangement of the magnetic patterns MGN, and this will be described later in detail.

The plurality of plates P0, P1 and P2 may include a center plate P0, a first plate P1, and a second plate P2. The center plate P0 may have a rectangular shape having four sides. In this embodiment, as shown in FIG. 4B, the center plate P0 may include a first side Sa and a second side Sb, which each extend in the first direction DR1 and oppose from each other in the second direction DR2, and a third side Sc and a fourth side Sd which each extend in the second direction DR2 and oppose from each other in the first direction DR1. In a case in which the substrate SUB has a rectangular shape having long sides extending in the first direction DR1 and short sides extending in the second direction DR2, the third side Sc and the fourth side Sd may each be at least provided to have a length corresponding to the short side of the substrate SUB. However, this is illustrated as an example, and the shape of the center plate P0 may be provided as various shapes according to the shape of the substrate SUB, and is not limited to any one embodiment.

The center plate P0 may be coupled to the rotary shaft RT. The rotary shaft RT may be disposed at or near a center of the center plate P0, and a center of the rotary shaft RT may match the center of the center plate P0. Accordingly, the center plate P0 may be rotated at an angle of rotation corresponding to the rotation of the rotary shaft RT, and, during the rotation of the rotary shaft RT, the center plate P0 may be rotated without a change in position on a plane. That is, the rotation of the center plate P0 may be controlled through the rotation of the rotary shaft RT. The center plate P0 may be rotated by a substantially 90-degree unit clockwise or counter-clockwise through the rotation of the rotary shaft RT. The first mode and the second mode may have a difference of about 90 degrees in angle of rotation. For example, the second mode may represent a state after the center plate is rotated about 90 degrees clockwise or rotated about 90 degrees counter-clockwise in the first mode. However, this is illustrative, and, in a case in which the center plate P0 has a polygonal shape, the angle of rogation of the center plate P0 may be set to a unit other than the 90-degree unit. For example, in a case in which the center plate P0 has an N-polygonal shape, the center plate P0 may be rotated by a 360/N-degree unit, and is not limited to any one embodiment. In FIGS. 4A to 4C, an embodiment is described with an example of a state in the first mode.

The first plate P1 and the second plate P2 may be disposed apart from each other with the center plate P0 disposed therebetween. In this embodiment, the first plate P1, the center plate P0, and the second plate P2 may be arranged in sequence along the first direction DR1.

The first plate P1 may be disposed at one side of the center plate P0. In this embodiment, the first plate P1 may face the third side Sc of the center plate P0 and be disposed adjacent to the third side Sc. The first plate P1 may have a rectangular shape on a plane. The rectangular shape of the first plate P1 may have a shape having a length corresponding to the one side of the center plate P0, and a smaller width than the center plate P0.

The second plate P2 may be disposed at the other side of the center plate P0. The one side of the center plate P0 and the other side of the center plate P0 may oppose each other along the first direction DR1. Thus, in this embodiment, the second plate P2 may face the fourth side Sd of the center plate P0 and be disposed adjacent to the fourth side Sd.

The second plate P2 may have a rectangular shape on a plane. The rectangular shape of the second plate P2 may have a shape having a length corresponding to the other side of the center plate P0, and a smaller width than the center plate P0. In this embodiment, the first plate P1 and the second plate P2 may have the same shape. In addition, the center plate P0 may have a square shape. However, this is illustrated as an example. According to the shape of the substrate SUB (see FIG. 1) or a shape of a deposition area, the center plate P0 may be designed to have a rectangular shape or the first plate P1 and the second plate P2 may be designed to have different shapes, and are not limited to any one embodiment.

The coupling parts CPP may be provided in plurality, and each of the plurality of coupling parts CPP may be coupled to the center plate P0. In this embodiment, the center plate P0 may have a rectangular shape having four sides, and two coupling parts CPP may be disposed on each of the sides. However, the number or the disposed positions of the coupling parts CPP are not limited thereto.

Each of the coupling parts CPP may include one portion at least partially overlapping the center plate P0 on a plane, and the other portion non-overlapping the center plate P0 on a plane. The portion of each of the coupling parts CPP may be physically coupled to the center plate P0, and the other portion may be coupled to a plate other than the center plate P0 or provided in a couplable state. In this embodiment, some of the coupling parts CPP may be disposed on the third side Sc of the center plate P0 and couple the first plate P1 and the center plate P0 to each other. Others of the coupling parts CPP may be disposed on the fourth side Sd of the center plate P0 and couple the second plate P2 and the center plate P0 to each other. The others of the coupling parts CPP may be disposed on the first side Sa or the second side Sb and provided in exposed states without being coupled to other plates.

The magnetic patterns MGN may include a center group G0, a first group G1, and a second group G2. The center group G0 may be disposed on the center plate P0 and coupled to a rear surface of the center plate P0. according to one or more embodiments, all of magnetic patterns MIG and M2G of the center group G0 may be covered by the center plate P0. In the magnetic patterns M1G and M2G of the center group G0, the magnetic patterns MIG and M2G having different polarities may be arranged in the form of a matrix to alternate with each other along the first direction and DR1 and the second direction DR2. A first magnetic pattern MIG of the center group G0 may have an N pole or an S pole, and a second magnetic pattern M2G disposed adjacent thereto may have an opposite pole, i.e., S pole or N pole.

The first group G1 may be disposed on the first plate P1 and coupled to a rear surface of the first plate P1. according to one or more embodiments, all of magnetic patterns M11 and M21 of the first group G1 may be covered by the first plate P1. In the magnetic patterns M11 and M21 of the first group G1, the magnetic patterns M11 and M21 having different polarities may be arranged in the form of a matrix to alternate with each other along the first direction and DR1 and the second direction DR2. In this embodiment, an array of two columns along the first direction DR1 by eight rows along the second direction DR2 is illustrated as an example of the matrix of the first group G1.

The first group G1 may be disposed adjacent to the center group G0 along the first direction DR1 and thus, the number of the magnetic patterns M11 and M21 of the first group G1 arranged along the second direction DR2 may be correspond to the number of the magnetic patterns MIG and M2G of the center group G0. In this embodiment, a shape of the matrix of the center group G0 may have an array of eight rows along the second direction DR2, and thus a shape of the matrix of the first group G1 has an array of eight rows corresponding thereto. The number of the magnetic patterns MIG and M2G of the first group G1, which are arranged along the first direction DR1, may be variously designed according to a length of the substrate SUB to be deposited in the first direction DR1, and is not limited to any one embodiment.

The second group G2 may be disposed on the second plate P2 and coupled to a rear surface of the second plate P2. according to one or more embodiments, all of the magnetic patterns M12 and M22 of the second group G2 may be covered by the second plate P2. In the magnetic patterns M12 and M22 of the second group G2, the magnetic patterns M12 and M22 having different polarities may be arranged in the form of a matrix to alternate with each other along the first direction and DR1 and the second direction DR2. In this embodiment, an array of two columns along the first direction DR1 by eight rows along the second direction DR2 is illustrated as an example of the matrix of the second group G2.

The second group G2 may be disposed adjacent to the center group G0 along the first direction DR1 and thus, the number of the magnetic patterns M12 and M22 of the second group G2 arranged along the second direction DR2 may be correspond to the number of the magnetic patterns MIG and M2G of the center group G0. That is, the second group G2 may correspond to the first group G1 faced in the first direction DR1, and a shape of a matrix of the second group G2 may have an array of eight rows corresponding thereto. The number of the magnetic patterns M12 and M22 of the second group G2, which are arranged along the first direction DR1, may be variously designed according to the length of the substrate SUB to be deposited in the first direction DR1, and is not limited to any one embodiment.

Referring to FIG. 4C, the masks MSK may be arranged in the first direction DR1. In the first mode, the magnetic patterns may provide a plurality of magnetic pattern rows PNH1 and PNH2 which are arranged along the second direction DR2 and each extend in the first direction DR1. An arrangement direction of the masks may cross an arrangement direction of the magnetic pattern rows. At least one of the masks MSK may overlap the first plate P1, overlap the second plate P2, or overlap the center plate P0. That is, the masks MSK may include at least one of a mask overlapping only the first plate P1, a mask overlapping only the second plate P2, or a mask overlapping only the center plate P0.

Each of the magnetic pattern rows PNH1 and PNH2 may include magnets having the same polarity as other magnets in that row. The magnetic pattern rows may include a first magnetic pattern row PNH1 and a second magnetic pattern row PNH2, where he first magnetic pattern and the second magnetic pattern differ. The first magnetic pattern row PNH1 may include magnetic patterns each having a first polarity. That is, the first magnetic pattern row PNH1 may include the first magnetic pattern MIG of the center group G0, the first magnetic pattern M11 of the first group G1, and the first magnetic pattern M12 of the second group G2. The magnetic patterns each having the first polarity are arranged apart from each other along the first direction DR1.

The second magnetic pattern row PNH2 may include magnetic patterns each having a second polarity. That is, the second magnetic pattern row PNH2 may include the second magnetic pattern M2G of the center group G0, the second magnetic pattern M21 of the first group G1, and the second magnetic pattern M22 of the second group G2. The magnetic patterns each having the second polarity are arranged apart from each other along the first direction DR1.

The first magnetic pattern row PNH1 and the second magnetic pattern row PNH2 may be each provided in plurality, and be arranged to alternate with each other. That is, in this embodiment, the plurality of first magnetic pattern rows PNH1 and the plurality of second magnetic pattern rows PNH2 may be alternately arranged along the second direction DR2.

According to an embodiment, the mask fixing part may be provided in the first mode, thereby providing the magnetic pattern rows PNH1 and PNH2 arranged along the second direction DR2 crossing the arrangement direction of the masks. Accordingly, the magnetic force may be substantially uniformly distributed to each of the masks, and fixing force to the masks may be uniformly provided to the entire area.

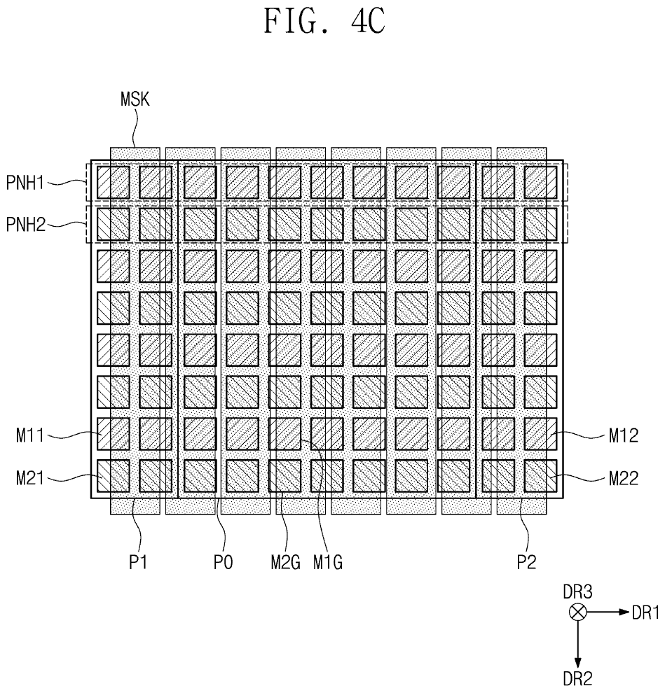

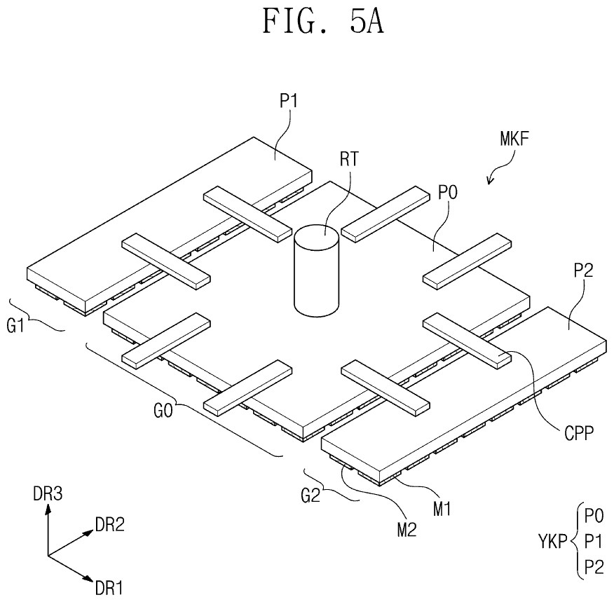

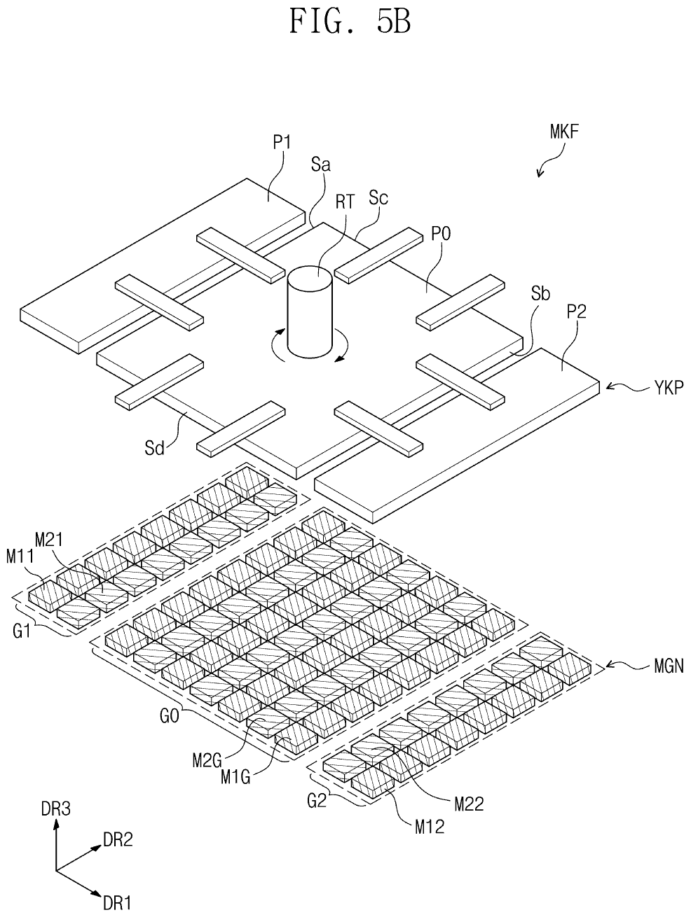

FIG. 5A is a perspective view illustrating a mask fixing part according to an embodiment as described herein. FIG. 5B is a disassembled perspective view of the mask fixing part illustrated in FIG. 5A. FIG. 5C is a rear view of the mask fixing part illustrated in FIG. 5A. FIGS. 5A to 5C each illustrate the mask fixing part in a second mode, and illustrate views corresponding to FIGS. 4A to 4C, respectively. Hereinafter, an embodiment is described with reference to FIGS. 5A to 5C.

As illustrated in FIGS. 5A and 5B, a mask fixing part MKF may be in the second mode. The mask fixing part MKF in the second mode may include a center plate P0 in the second mode, a first plate P1 in the second mode, and a second plate P2 in the second mode.

The center plate P0 in the second mode may be provided by rotating the center plate P0 in the first mode at a predetermined angle. In this embodiment, the center plate P0 in the second mode may correspond to the center plate P0 in the first mode rotated about 90 degrees counter-clockwise on a plane defined by the first direction DR1 and the second direction DR2. Accordingly, respective positions of the first to fourth sides Sa, Sb, Sc and Sd of the center plate P0 in the first mode may be changed. Specifically, the first side Sa may be moved to a position facing the first plate P1, and the second side Sb may be moved to a position facing the second plate P2. The third side Sc and the fourth side Sd may be moved to positions at which the third side Sc and the fourth side Sd are exposed without facing plates.

The first plate P1 in the second mode may be substantially the same as the first plate P1 in the first mode in that the first plate P1 is coupled to the center plate P0 through coupling parts CPP. However, a side faced by the first plate P1 in the second mode may be changed to the first side Sa of the center plate P0, and accordingly, an arrangement of magnetic patterns of a first group G1 disposed on the first plate P1 in the second mode may be substantially changed.

The second plate P2 in the second mode may be substantially the same as the second plate P2 in the first mode in that the second plate P2 is coupled to the center plate P0 through the coupling parts CPP. However, a side faced by the second plate P2 in the second mode may be changed to the second side Sb of the center plate P0, and accordingly, the arrangement of a magnetic patterns of a second group G2 disposed on the second plate P2 in the second mode may be substantially changed.

Magnetic patterns MGN will be specifically described with reference to FIGS. 5B and 5C. The magnetic patterns MGN in the second mode may include a center group G0 in the second mode, a first group G1 in the second mode, and a second group G2 in the second mode. The center group G0 in the second mode may include magnetic patterns having a different array from the magnetic patterns of the center group G0 in the first mode. The center group G0 in the second mode may include a plurality of first magnetic patterns MIG and a plurality of second magnetic patterns M2G, and a direction in which the first magnetic patterns MIG and the second magnetic patterns M2G are alternately arranged may be the second direction DR2. Specifically, the first magnetic patterns MIG of the center group G0 in the second mode are disposed apart from each other along the first direction DR1, and the second magnetic patterns M2G of the center group G0 in the second mode are disposed apart from each other along the first direction DR1. The first magnetic patterns MIG and the second magnetic patterns M2G of the center group G0 in the second mode may be alternately arranged along the second direction DR2. That is, in the center group G0 in the second mode, a magnetic pattern having a first polarity and a magnetic pattern having a second polarity may be alternately arranged along the second direction DR2. The first magnetic patterns MIG of the center group G0 may each have an N pole or an S pole, and each of the second magnetic patterns M2G disposed adjacent thereto may have an opposite pole, i.e., S pole or N pole.

The magnetic patterns of the first group G1 disposed on the first plate P1 in the second mode may include a plurality of first magnetic patterns M11 each having the first polarity, which are arranged along the first direction DR1, and a plurality of second magnetic patterns M21 each having the second polarity which are arranged along the first direction DR1. In the magnetic patterns of the first group G1 disposed on the first plate P1 in the second mode, a magnetic pattern having the first polarity and a magnetic pattern having the second polarity may be alternately arranged along the second direction DR2.

The magnetic patterns of the second group G2 disposed on the second plate P2 in the second mode may include a plurality of first magnetic patterns M12 each having the first polarity, which are arranged along the first direction DR1, and a plurality of second magnetic patterns M22 each having the second polarity which are arranged along the first direction DR1. In the magnetic patterns of the second group G2 disposed on the second plate P2 in the second mode, a magnetic pattern having the first polarity and a magnetic pattern having the second polarity may be alternately arranged along the second direction DR2.

Referring to FIG. 5C, the masks MSK may be arranged along the second direction DR2. At least one of the masks MSK may overlap all of the first plate P1, the second plate P2, and the center plate P0. That is, each of the masks MSK may have a length extending so as to overlap all of the first plate P1, the center plate P0, and the second plate P2.

In this embodiment, the magnetic patterns may provide a plurality of magnetic pattern columns PNV1 and PNV2 which are arranged along the first direction DR1 and each extend in the second direction DR2. An arrangement direction of the masks may cross an arrangement direction of the magnetic pattern columns. Each of the magnetic pattern columns PNV1 and PNV2 may include magnets having the same polarity.

The magnetic pattern columns PNV1 and PNV2 may include a first magnetic pattern column PNV1 and a second magnetic pattern column PNV2. The first magnetic pattern column PNV1 may include magnetic patterns each having the first polarity. That is, the first magnetic pattern column PNV1 may include only the first magnetic patterns M11 of the first group G1, include only the first magnetic patterns MIG of the center group G0, or include only the first magnetic pattern M12 of the second group G2. The magnetic patterns each having the first polarity are arranged apart from each other along the second direction DR2.

The second magnetic pattern column PNV2 may include magnetic patterns each having the second polarity. That is, the second magnetic pattern column PNV2 may include only the second magnetic patterns M21 of the first group G1, include only the second magnetic patterns M2G of the center group G0, or include only the second magnetic pattern M22 of the second group G2. The magnetic patterns each having the second polarity are arranged apart from each other along the second direction DR2.

The first magnetic pattern column PNV1 and the second magnetic pattern column PNV2 may be each provided in plurality, and be arranged to alternate with each other. That is, in this embodiment, the plurality of first magnetic pattern columns PNV1 and the plurality of second magnetic pattern columns PNV2 may be alternately arranged along the first direction DR1.

According to an embodiment, the mask fixing part may be provided in the second mode, thereby providing the magnetic pattern columns PNV1 and PNV2 arranged along the first direction DR1 crossing the second direction DR2 that is the arrangement direction of the masks. Accordingly, the magnetic force may be substantially uniformly distributed to each of the masks, and the fixing force to the masks may be uniformly provided to the entire area.

In addition, according to an embodiment, the rotatable center plate P0 and the plates P1 and P2 coupled thereto may be differentially provided according to the modes, thereby providing the mask fixing part MKF capable of forming the magnetic force in a direction crossing the arrangement direction of the masks even when the arrangement direction of the masks is changed. According to an embodiment, the magnetic patterns MGN may be provided in an “island shape” as further described herein, and the center plate P0 may be set to be rotatable, thereby stably providing a magnetic environment for coupling the masks with respect to various arrangement directions of the masks. Moreover, the plates P1 and P2 capable of providing the magnetic patterns MGN having a different array according to each mode may be stably separated and coupled using the coupling part CCP, thereby easily replacing the plates P1 and P2. Therefore, the mask fixing part applicable to various environments, in which the size or the position of the substrate may be changed, and the deposition apparatus including the mask fixing part may be provided.

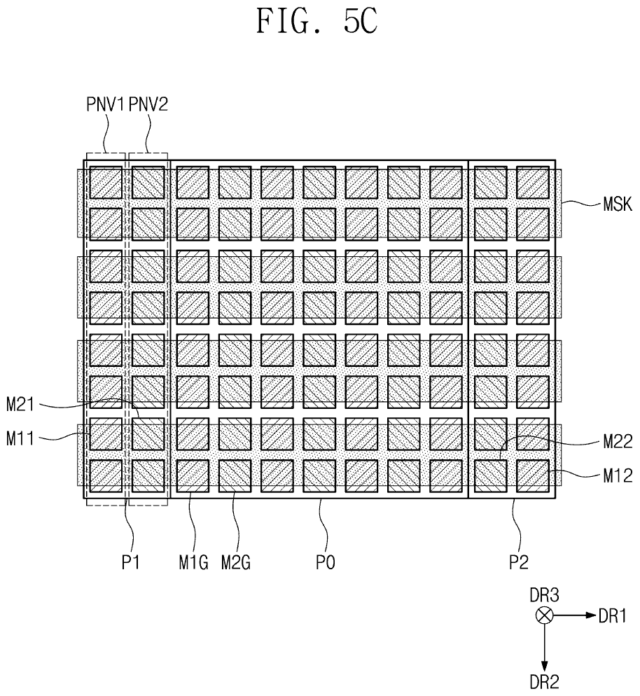

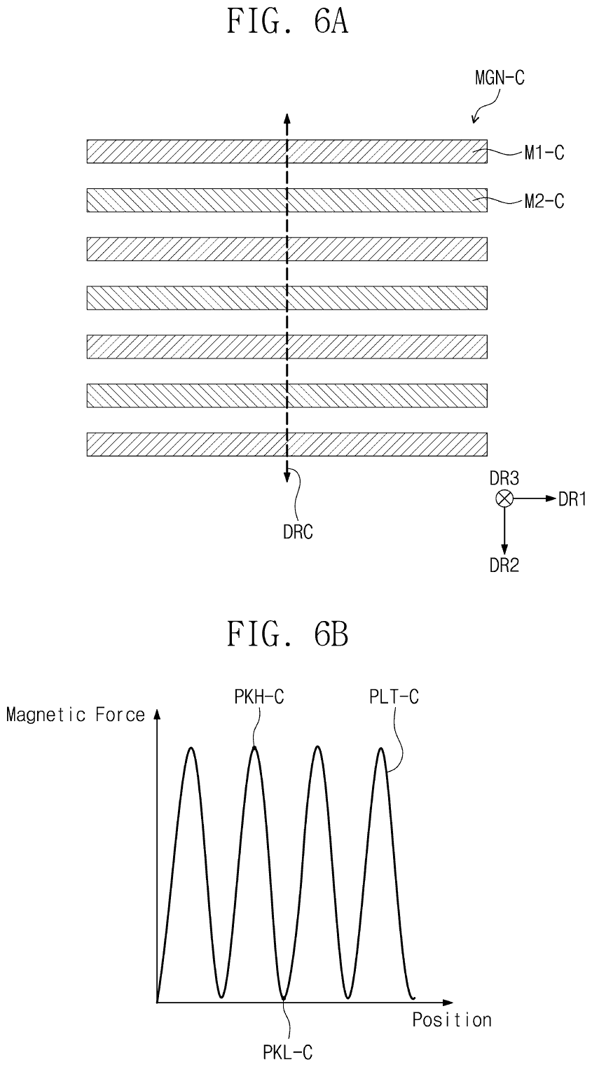

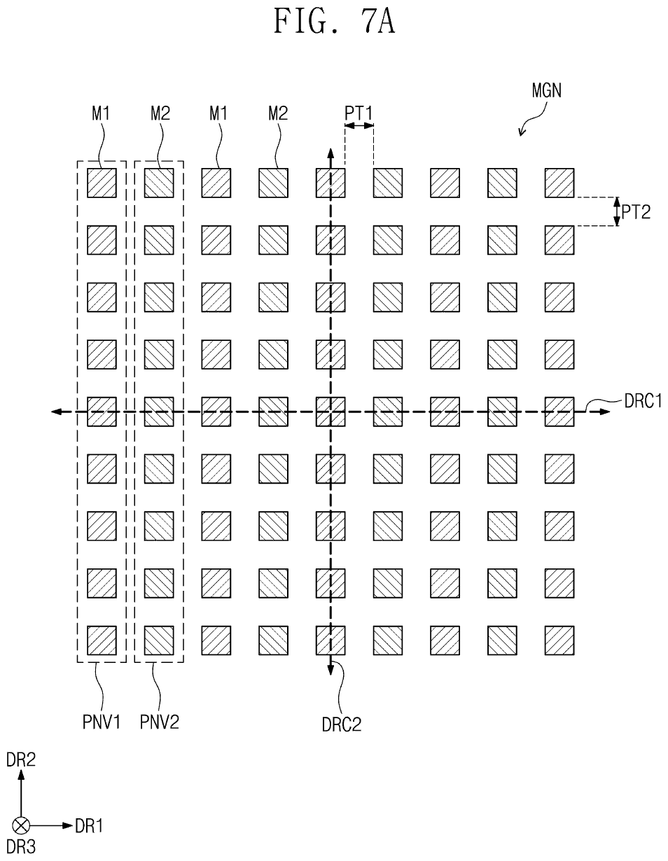

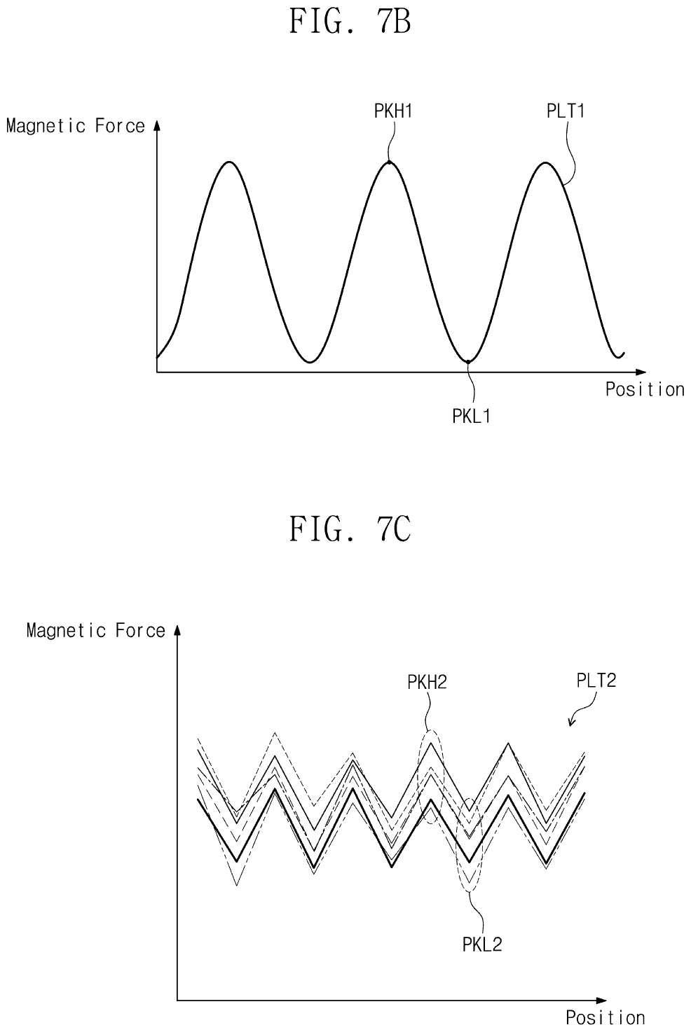

FIG. 6A illustrates magnetic patterns according to a comparative example of an embodiment as described herein. FIG. 6B is a graph illustrating a magnetic force distribution for positions of the magnetic patterns illustrated in FIG. 6A. FIG. 7A illustrates magnetic patterns according to a comparative example of an embodiment as described herein. FIGS. 7B and 7C are each a graph illustrating a magnetic force distribution for positions of the magnetic patterns illustrated in FIG. 7A. For concise explanation, FIGS. 6A and 7A each illustrate an array of the magnetic patterns in a state when viewed in the third direction DR3 so as to correspond to FIG. 4C. Hereinafter, an embodiment is described with reference to FIGS. 6A to 7C.

Referring to FIG. 6A, the magnetic patterns according to the comparative example may include a first magnetic pattern M1-C and a second magnetic pattern M2-C. The first magnetic pattern M1-C and the second magnetic pattern M2-C may have different polarities. That is, when the first magnetic pattern M1-C has N pole magnetism, the second magnetic pattern M2-C may have S pole magnetism. Conversely, when the first magnetic pattern M1-C has S pole magnetism, the second magnetic pattern M2-C may have N pole magnetism. Each of the first magnetic pattern M1-C and the second magnetic pattern M2-C may have a bar shape having a length extending in the first direction DR1. The first magnetic pattern M1-C and the second magnetic pattern M2-C may be each provided in plurality, and be arranged to alternate with each other along the second direction DR2 crossing a longitudinal direction.

FIG. 6B illustrates magnetic forces measured along an arrangement direction DRC (shown in FIG. 6A) of the magnetic patterns of FIG. 6A. In a magnetic force graph PLT-C according to the comparative example, a peak PKH-C may correspond to a polarity of one of the first magnetic pattern M1-C and the second magnetic pattern M2-C, and a trough PKL-C may correspond to a polarity of the other of the first magnetic pattern M1-C and the second magnetic pattern M2-C. As the first magnetic pattern M1-C and the second magnetic pattern M2-C which have different polarities are alternately disposed along the arrangement direction DRC, the magnetic force graph PLT-C according to the comparative example may have a shape having a predetermined cycle in which opposite polarities are alternately shown according to positions. For example, the magnetic force graph PLT-C according to the comparative example may have a sine curve, but is not limited thereto.

Referring to FIG. 7A, magnetic patterns according to an embodiment as described herein may include a first magnetic pattern M1 and a second magnetic pattern M2 which have different polarities, and each of the first magnetic pattern M1 and the second magnetic pattern M2 may have an island shape. An “island shape” is as follows: the first magnetic pattern M1 and the second magnetic pattern M2 may be each provided in plurality, and the plurality of first magnetic patterns M1 and the plurality of second magnetic patterns M2 may be arranged apart from each other along the first direction DR1 and arranged apart from each other along the second direction DR2. In this embodiment, each of the first magnetic pattern M1 and the second magnetic pattern M2 is illustrated as having a square shape. However, this is illustrated as an example, and each of the first magnetic pattern M1 and the second magnetic pattern M2 may have various shapes such as a circular shape, a polygonal shape, or an oval shape, and is not limited to any one embodiment.

The first magnetic pattern M1 and the second magnetic pattern M2 may have an array with a separation gap of a first pitch PT1 in the first direction DR1 and a separation gap of a second pitch PT2 in the second direction DR2. In this embodiment, the first pitch PT1 and the second pitch PT2 are illustrated as being substantially the same, but are not limited thereto. The first pitch PT1 and the second pitch PT2 may be designed independently of each other, and are not limited to any one embodiment.

In this embodiment, the magnetic patterns are illustrated as being in a second mode. That is, the magnetic patterns may be in the form of an array including a plurality of magnetic pattern columns PNV arranged along the first direction DR1. Accordingly, the plurality of first magnetic patterns M1 and the plurality of second magnetic patterns M2 may be arranged to alternate with each other along the first direction DR1, and, along the second direction DR2, the plurality of first magnetic patterns M1 may be arranged apart from each other in one column, and the plurality of second magnetic patterns M2 may be arranged apart from each other in another column.

A graph PLT1 illustrated in FIG. 7B shows magnetic forces measured along an arrangement direction DRC1 (shown in FIG. 7A) of magnetic pattern columns PNV1 and PNV2, and graphs PLT2 illustrated in FIG. 7C show magnetic forces measured along an extension direction DRC2 (shown in FIG. 7A) for the magnetic pattern columns PNV1 and PNV2, respectively. The graphs PLT2 illustrated in FIG. 7C illustrate magnetic force distributions for six magnetic pattern columns PNV of the magnetic pattern columns PNV illustrated in FIG. 7A.

In the graph PLT1 illustrated in FIG. 7B, a peak PKH1 may correspond to a polarity of one of the first magnetic pattern M1 and the second magnetic pattern M2, and a trough PKL1 may correspond to a polarity of the other of the first magnetic pattern M1 and the second magnetic pattern M2. As the first magnetic pattern M1 and the second magnetic pattern M2 which have different polarities are alternately disposed along the arrangement direction DRC1, the graph PLT1 for the magnetic forces shown along the arrangement direction DRC1 may have a shape having a predetermined cycle in which opposite polarities are alternately shown according to the positions. For example, the graph PLT1 may have a sine curve, but is not limited thereto.

In the graphs PLT2 illustrated in FIG. 7C, a peak PKH2 may correspond to a polarity of one of the first magnetic pattern M1 and the second magnetic pattern M2, and a trough PKL2 may correspond to an empty space, specifically to an intermediate point between the magnetic patterns M1 and M2. For example, in the first magnetic pattern column PNV1, the trough PKL2 may correspond to an intermediate point between two first magnetic patterns M1 spaced apart from each other in the second direction DR2. In the second magnetic pattern column PNV2, the trough PKL2 may correspond to an intermediate point between two second magnetic patterns M2 spaced apart from each other in the second direction DR2. The intermediate points may be substantially equally affected by the magnetic force of the two adjacent magnetic patterns, and thus the magnetic force at the intermediate point may correspond to substantially ½ of a polarity at the peak PKH2. As the magnetic patterns are arranged with the predetermined pitch PT2 in the magnetic pattern columns PNV1 and PNV2, the graph PLT2 for the magnetic forces measured along the extension direction DRC2 may be shown as a graph having a cycle in which the peak PKH2 and the trough PKL2 are repeated according to the positions.

According to an embodiment, the graph PLT1 shown along the arrangement direction DRC1 may have a magnetic force distribution corresponding to a graph in magnetic patterns each having a bar shape. In addition, the graph PLT2 shown along the extension direction DRC2 may have a predetermined cycle, but have a sufficient magnetic force even at the trough PKL2. Thus, sufficient magnetic force for fixing the masks with respect to the extension direction DRC2 may be provided simply by using the magnetic patterns having an island shape. Here, the first pitch PT1 or the second pitch PT2 may be controlled to variously adjust the magnetic force distribution. According to an embodiment, the magnetic force having a sufficient magnitude may be provided simply by using the magnetic patterns having an island shape, and the magnetic force having a relatively uniform distribution for the entire area of the mask fixing part may be provided.

According to the embodiment, the deposition apparatus capable of stably fixing the masks may be provided.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the technical scope of the disclosure is not limited to the contents described in the detailed description of the specification, but should be determined by the claims.

What is claimed is:

1. A deposition apparatus comprising:
a deposition chamber which provides an inner space;
a deposition source provided in the inner space;
a plate which is provided in the inner space and rotatable;
a plurality of magnetic patterns arranged on a surface of the plate and in “n” rows and “m” columns, wherein “n” and “m” are each a natural number of 1 or more; and
a plurality of masks disposed between the plate and the deposition source and fixed by the plurality of magnetic patterns,
wherein the plate comprises:
a center plate on which magnetic patterns of a center group are disposed and which is rotatable;
a first plate on which magnetic patterns of a first group are disposed and which is coupled to one side of the center plate; and
a second plate on which magnetic patterns of a second group are disposed and which is spaced apart from the first plate with the center plate therebetween in a first direction,
wherein the plate undergoes a change in mode to a first mode or a second mode through rotation,
wherein the first plate in the first mode and the first plate in the second mode include the plurality of magnetic patterns having different arrays from each other.

2. The deposition apparatus of claim 1, wherein the center plate rotates about 90 degrees clockwise or counter-clockwise to undergo the change in mode to the first mode or the second mode.

3. The deposition apparatus of claim 2, wherein, in the first mode, the plurality of masks are arranged in the first direction, and
each of the plurality of magnetic patterns faces a first magnetic pattern having the same polarity in the first direction, and faces a second magnetic pattern having a different polarity in a second direction parallel to a column direction of the plurality of magnetic patterns.

4. The deposition apparatus of claim 3, wherein at least one of the plurality of masks overlaps only one of the center plate, the first plate, and the second plate.

5. The deposition apparatus of claim 3, wherein, in the second mode, the plurality of masks are arranged along the second direction crossing the first direction, and
each of the plurality of magnetic patterns faces a third magnetic pattern having the same polarity in the second direction, and faces the second magnetic pattern having the different polarity in the second direction parallel to the column direction of the plurality of magnetic patterns.

6. The deposition apparatus of claim 5, wherein at least one of the plurality of masks overlaps all of the center plate, the first plate, and the second plate.

7. The deposition apparatus of claim 1, wherein “m” is less than “n.”

8. The deposition apparatus of claim 1, wherein the center plate has an N-polygonal shape, and
wherein the center plate rotates about 360/N degrees clockwise or counter-clockwise in the first mode to undergo the change in mode to the second mode.

9. The deposition apparatus of claim 8, wherein the center plate has a square shape, and
each of the first plate and the second plate has a rectangular shape.

10. The deposition apparatus of claim 1, wherein each of the masks is a fine metal mask (FMM).

11. The deposition apparatus of claim 1, further comprising a coupling part which couples the center plate and the first plate or the center plate and the second plate to each other,
wherein the first plate or the second plate is detachable from the coupling part.

12. A deposition apparatus comprising:
a deposition chamber which provides an inner space;
a deposition source provided in the inner space;
a plurality of masks disposed apart from the deposition source and arranged along one direction; and
a mask fixing part rotatable clockwise or counter-clockwise on a plane and which fixes the masks,
wherein the mask fixing part comprises:
a plate provided in the inner space and rotatable; and
a plurality of first magnetic patterns each having a first polarity, and a plurality of second magnetic patterns each having a second polarity different from the first polarity and spaced apart from the plurality of first magnetic patterns, the plurality of first magnetic patterns and the plurality of second magnetic patterns being disposed on the plate,
wherein the plurality of first magnetic patterns are arranged along an intersection direction crossing the one direction,
the plurality of second magnetic patterns are arranged along the intersection direction, and
the plurality of first magnetic patterns and the plurality of second magnetic patterns are alternately arranged along the one direction.

13. The deposition apparatus of claim 12, wherein the deposition chamber comprises a bottom surface defined by a first direction and a second direction crossing each other, and
the mask fixing part undergoes a change in mode to a first mode or a second mode through rotation,
wherein, in the first mode, the one direction is parallel to the first direction, and
in the second mode, the one direction is parallel to the second direction.

14. The deposition apparatus of claim 13, wherein the plate comprises:
a center plate which is rotatable; and
a first plate and a second plate, wherein, in the first mode, the first plate and the second plate are disposed apart from each other with the center plate therebetween in the first direction, and, in the second mode, the first plate and the second plate are disposed apart from each other with the center plate therebetween in the second direction,
wherein the center plate rotates clockwise or counter-clockwise to undergo the change in mode to the first mode or the second mode.

15. The deposition apparatus of claim 14, wherein, in the first mode, the first plate comprises a first group in which first magnetic patterns having different polarities are arranged along the second direction, and
wherein, in the second mode, the first plate comprises a second group in the second mode in which second magnetic patterns having the different polarities are arranged along the first direction.

16. The deposition apparatus of claim 14, wherein the first plate and the second plate are detachable from the center plate.

17. The deposition apparatus of claim 14, wherein a difference in angle of rotation between the first mode and the second mode is about 90 degrees.

18. The deposition apparatus of claim 14, wherein magnetic patterns disposed on the center plate are arranged in “a” rows and a columns, and
wherein “a” is a natural number of 1 or more.

19. The deposition apparatus of claim 12, wherein magnetic patterns are arranged in a form of a matrix with “n” rows and “m” columns, and
wherein the “n” rows are defined in the one direction, the “m” columns are defined in the intersection direction, and “n” and “m” are each a natural number of 1 or more, and
wherein “n” is less than “m.”

20. A method for manufacturing a display device, the method comprising:
providing a deposition apparatus, the deposition apparatus comprising a deposition chamber which provides an inner space;
a deposition source provided in the inner space;
a plate which is provided in the inner space and rotatable;
a plurality of magnetic patterns arranged on a surface of the plate and in “n” rows and “m” columns, wherein “n” and “m” are each a natural number of 1 or more; and
a mask disposed between the plate and the deposition source and fixed by the plurality of magnetic patterns,
wherein the plate comprises:
a center plate on which magnetic patterns of a center group are disposed and which is rotatable;
a first plate on which magnetic patterns of a first group are disposed and which is coupled to one side of the center plate; and
a second plate on which magnetic patterns of a second group are disposed and which is spaced apart from the first plate with the center plate therebetween in a first direction,
wherein the plate undergoes a change in mode to a first mode or a second mode through rotation,
wherein the first plate in the first mode and the first plate in the second mode include the plurality of magnetic patterns having different arrays from each other;
providing the mask on a substrate; and
depositing the deposition source on the substrate.
